(19) United States
(12) Patent Application Publication
(10) Pub. No.: US 2010/0321893 A1
(43) Pub. Date: Dec. 23, 2010

(54) Heat Dissipation Packaging for Electrical Components

(76) Inventor: Peter Scott Andrews, Durham, NC (US)

Correspondence Address: Peter Scott Andrews, 221 Continental Drive, Durham, NC, 27712, US

(21) Appl. No.: 12/488,546

(22) Filed: Jun. 20, 2009

(51) Int. Cl. H05K 7/20; B21D 53/02

(52) U.S. Cl. 361/707; 29/890.03; 361/704; 361/714

(57) ABSTRACT

The emphasis for transporting heat energy to ambient in an efficient manner is critical for many semiconductor components to maintain highest performance. A heat dissipation system with low thermal resistance for the packaging of high power electrical components, and the methods for assembling a low thermal resistance system, is proposed. Unique in this method is the emphasis on moving heat with a primary thermal conductor away from the source and creating large area interface zones to improve heat transfer.

### FIELD OF THE INVENTION

This invention relates to packaging of electrical components and methods of packaging electrical components, and more particularly to heat extraction and methods of heat extraction for electrical components such as high power Light Emitting Diode (LED) components.

### BACKGROUND OF THE INVENTION

Electrical devices and components, such as power components and high-power LEDs, have a high power consumption per area generating a significant amount of heat in a small area which, if not managed, can degrade the performance of the device and/or system, and can provide localized hot spots that are too-hot-too-touch. This invention relates to packaging and packaging methods for electronic components where heat management is critical for package and/or system performance and/or handling.

The necessity for management of heat to preserve performance of electrical devices is widely known. LED components are particularly sensitive in that their optical output, or efficiency, is directly related to the junction temperature of the LED device. Power components, used for power conditioning, also generate a significant amount of heat and many of them come packaged with built-in heat sinks for thermal dissipation. There is a large industry surrounding varieties of heat sinks, thermal pads and thermal compounds for enhancing conduction to heat dissipating structures for power conditioning or heat generating or heat sensitive components.

The current trend in LED components, to address a growing market segment for lighting-class-products and other niche markets, is to increase the Lumens that can be achieved from a single package. This increase is accomplished by increasing the rated power that can be input and efficiently converted to light. Thus high-power-LED components are requiring more rigorous heat management than ever before.

For the conduction of heat away from a high-power-LED component, the most common methods are the use of thermal-vias within a Printed Circuit Board or Printed Wiring Board (PCB/PWB) to conduct heat to bottom side metal, or the use of a Metal-Core-Printed-Circuit-Board or Metal-Core-Printed-Wiring-Board (MCPCB/PWB) which also offers good thermal conduction from the LED component. The PCB/PWB or MCPCB/PWB is then attached, usually mechanically with the aid of thermal conductive grease or thermal conductive pad, to a large heat-sink or to a forced-convection-fin system to dissipate the heat.

PCB/PWB with thermal vias have a disadvantage in that the area of each via is constrained usually small requiring multiple thermal vias to be used to maximize the area of increased heat transfer. Also the thermal conductivity of plated-through or filled thermal-vias is generally not as good as “melted” metals. A further loss of conduction efficiency is incurred by the interface from the back of the PCB/PWB to the heat dissipating component.

The MCPCB/PWB has a disadvantage in that there is a dielectric layer between the metal core and printed circuit traces. There has been much work to increase the heat transfer to the metal core as efficiently as possible by careful choice of dielectric compounds and carefully controlling thickness, however electrically-insulating materials have generally poor thermal conductivity. When comparing the thermal resistance of a thin solder layer directly bonded to Copper, versus a thin solder layer bonded to a thin Copper trace, which is bonded to a dielectric layer, which is bonded to a metal core (typically Aluminum), the advantages in thermal resistance of the former are apparent.

When multiple electrical components are designed on a single board, the thermal constraints frequently limit the design options. Also as with PCB/PWBs, the transfer of heat across the interface from the MCPCB/PWB to the heat-sink (or heat dissipating device) is critical for thermal efficiency. This interface is typically by mechanical attachment with the aid of thermal conductive grease or thermal conductive pad to maximize surface area contact.

In yet other embodiments on the market today, heat-pipes are used to transfer heat away through evaporative/condensing cycling to heat dissipation surfaces. In other embodiments, active cooling is employed to manage heat at the LED or heat generating device by using Thermo-Electric Cooling devices to control heat flow and dissipation. Both of these are relatively expensive options for heat dissipation.

LED packaged components are rated with a thermal resistance in degrees Celsius per Watt, C/W. This is generally referenced as the thermal resistance from the LED junction temperature, which affects LED performance, to the solder point on the LED component. The amount of Lumens over time that a consumer can get from a High-Power-LED-Component (HPLEDCOMP) at a given power input is directly related to how well the thermal resistance components are managed during assembly of the system. The current state of the art has limitations in the efficiency of thermal transfer, or has limitations in how the supporting system can be designed to keep thermal resistance low, or incurs a higher cost to achieve high efficiency in heat removal.

### SUMMARY

A heat dissipation system with low thermal resistance for the packaging of high power electrical components, and the methods for assembling a low thermal resistance system, is proposed. Unique in this method is the emphasis on moving heat with a primary thermal conductor away from the source and creating large area interface zones to improve heat transfer and lower temperatures through energy spreading. A heat dissipation system according to some embodiments of the invention include an electrical component, electrical connections for power/signal on the electrical component, a thermal connection for heat dissipation to the electrical component and to a primary heat conductor, and a primary heat conductor to dissipate heat to ambient conditions. The direct coupling of a primary heat conductor to the electronic device and moving heat through packaging, mounting, and structural elements to get to ambient heat transfer is part of the system.

The heat dissipation system may further include that the primary heat conductor is also electrically tied to one of the signal or power leads of the electrical component. The primary heat conductor may also provide structural support, or pass through structural components to get to ambient conditions.

The heat dissipation system may further include a secondary heat conductor, which takes energy from the primary heat conductor and conducts this energy to ambient conditions. The secondary heat conductor may be of a different material than the primary heat conductor as much more surface area is available for transfer from the primary heat conductor as compared to the area available from the electronic device to the primary heat conductor. The secondary heat conductor can also provide structural support for the larger assembly. The secondary heat conductor can further provide features such as cavities for sealing around the electronic component to provide protection such as waterproofing for underwater operation of the larger assembly.

Further features of the secondary heat conductor may include a precise machined cavity for thermal mating to the primary heat conductor. Some embodiments of the invention provide methods for coupling the primary heat conductor to the secondary heat conductor. One such method is to utilize the physical properties of the coefficient of thermal expansion of the materials by heating the secondary conductor and cooling the primary conductor prior to insertion of the primary heat conductor into the secondary heat conductor. Upon equalization of temperature, the fit will be tight ensuring good thermal conduction between the two heat conductors.

The heat dissipation system may further include the use of a thermal-interface-compound such as thermal grease to ensure the good thermal conduction interface between primary and secondary heat conductors. Other embodiments of the invention include the use of fasteners in multiple fashions, machined features to utilize spring forces within the primary heat conductor, machined features to enable interlocking of the parts and maximizing thermal contact, metallurgical joining of the two conductors, or mechanical deformation such as crimping, all to ensure good thermal conduction through low resistance contact.

The heat dissipation system by further include a threaded interface between the primary and secondary heat conductor to maximize surface and contact area between the primary and secondary heat conductors.

The heat dissipation system may further include a third component or third heat conductor with the purpose of enhancing contact between the primary and secondary heat conductors. In some embodiments, the third heat conductor can also provide a lower thermal resistance path between the first and secondary heat conductor than without the third heat conductor. In some embodiments of the invention, the third heat conductor provides a force against the primary and secondary heat conductor to maintain good thermal contact between the heat conductors. In other embodiments of the invention, multiple tertiary components are used to enhance heat transfer.

Some embodiments of the invention comprise multiple electrical components mounted to the primary heat conductor. Other embodiments comprise multiple primary heat conductors within a single secondary conductor. Other embodiments comprise multiple secondary heat conductors.

One embodiment of the invention comprises the electrical component, the thermal connection for heat dissipation from the electrical component, a primary heat conductor, and an electrical-connection-component which has a shaped cutout such that the electrical connection to the component can be made after the connection to the primary heat conductor by inserting and twisting the electrical-connection-component to align pads from the electrical component to the electrical-connection-component.

In yet another embodiment of the invention, the thermal interface between the primary and secondary heat conductor is maintained by a spring force exerted by the secondary heat conductor. The method by which this force is maintained is by constructing the secondary heat conductor in such a manner that it can be flexed to allow insertion of the primary heat conductor and then released which applies the clamping force to maintain good thermal contact with the primary heat conductor. Another embodiment of the invention is to flex or bend the secondary heat conductor post insertion to close any gaps and ensure good thermal contact between the primary and secondary heat conductor.

In other embodiments of the invention, a plurality of electrical components can be held and heat dissipated with the flexing of the secondary heat conductor to contact the primary heat conductor(s).

A heat dissipating system may further include an expansion body around which the primary heat conductor is wrapped, and this subassembly is then inserted into the secondary heat conductor. This configuration uses the Coefficient of Thermal Expansion (CTE) of different materials to assure a path of low thermal resistance is maintained when heat is needed to be dissipated. Some methods may further include the heating of the secondary heat conductor and cooling of the primary heat conductor subassembly prior to assembly of the primary heat conductor subassembly into the secondary heat conductor. This system may also comprise a plurality of electrical components. This system may also comprise a plurality of primary-heat-conductors-and-expansion-body subassemblies within a secondary heat conductor.

A heat dissipating system comprising an electrical component, a thermal connection for heat dissipation from the electrical component to a primary heat conductor, and a primary-heat-spreading body for transferring heat from the primary heat conductor to a secondary heat conductor. Some methods may further include utilization of materials so that the primary heat conductor has a lower CTE than the primary-heat-spreading body to assure a good thermal interface is maintained when heat is being conducted away from the electrical component. Some methods may further include thermally-expanding the secondary heat conductor relative to and prior to assembly of the primary-heat-spreading subassembly (comprising the electrical device, the primary heat conductor, and the primary-heat-spreading body). This method will assure a tight contact and thus good thermal conduction between the secondary heat conductor and the primary-heat-spreading subassembly.

Some embodiments of the heat dissipation system that utilize a primary-heat-spreading body may include inserting the primary heat conductor into a feature in the primary-heat-spreading body or may include the inserting the primary heat conductor completely through the primary-heat-spreading and then forming the inserted primary heat conductor on the opposite side of the primary-heat-spreading body to assure good structural contact between the pieces. Other means by which the primary heat conductor can be thermally coupled to the primary-heat-spreading body include fastening with fasteners, metallurgical bonding, use of thermal-conducting compound, or other such means. Embodiments using a primary-heat-spreading body can include a plurality of electrical devices, and or a plurality of primary-heat-spreading body subassemblies per secondary heat conductor.

### BRIEF DESCRIPTION OF THE DRAWINGS

FIG. 1 is a cross-sectional view of a primary heat conductor dissipating heat to ambient.

FIG. 2A is a cross-sectional view of a primary heat conductor coupled to a secondary heat conductor dissipating heat to ambient.

FIG. 2B is a cross-sectional view of a primary heat conductor coupled with a fastener to a secondary heat conductor dissipating heat to ambient.

FIG. 2C is a cross-sectional view of a primary heat conductor coupled with wedge action by a fastener to a secondary heat conductor dissipating heat to ambient.

FIG. 2D is a cross-sectional view of a primary heat conductor coupled with spring force to a secondary heat conductor dissipating heat to ambient.

FIG. 2E is a cross-sectional view of a primary heat conductor coupled with locking features to a secondary heat conductor dissipating heat to ambient.

FIG. 2F is a cross-sectional view of a primary heat conductor coupled via metallurgical joining or crimping to a secondary heat conductor dissipating heat to ambient.

FIG. 3 is a cross-sectional view of a primary heat conductor coupled via threads to a secondary heat conductor dissipating heat to ambient.

FIG. 4A is a cross-sectional view of a primary heat conductor coupled with spring force from a spring to a secondary heat conductor dissipating heat to ambient.

FIG. 4B is a cross-sectional view of a primary heat conductor coupled via pinning to a secondary heat conductor dissipating heat to ambient.

FIG. 4C is a cross-sectional view of a primary heat conductor coupled with a fastener to a secondary heat conductor dissipating heat to ambient.

FIG. 4D is a cross-sectional view of a primary heat conductor coupled with a fastener such as a set-screw to a secondary heat conductor dissipating heat to ambient.

FIG. 4E is a cross-sectional view of a primary heat conductor coupled with a wedge to a secondary heat conductor dissipating heat to ambient.

FIG. 5 is a cross-sectional view of a PCB in relation to a primary heat conductor coupled to a secondary heat conductor dissipating heat to ambient.

FIG. 6 is a top view of a PCB with cutout for assembly method to LED.

FIG. 7 is a cross-sectional view of a primary heat conductor coupled via spring action of the secondary heat conductor which is dissipating heat to ambient.

FIG. 8A is a cross-sectional view of a primary heat conductor coupled to a secondary heat conductor with the aid of an expansion-body.

FIG. 8B is a top view of a plurality of electrical devices on primary heat conductors coupled to a secondary heat conductor dissipating heat to ambient.

FIG. 9A is a cross-sectional view of a primary heat conductor coupled to a primary-heat-spreading body which is coupled to a secondary heat conductor dissipating heat to ambient.

FIG. 9B is a top view of a primary heat conductor coupled to a primary-heat-spreading body which is coupled to a secondary heat conductor dissipating heat to ambient.

FIG. 9C is a cross-sectional view of a primary heat conductor inserted into a primary-heat-spreading body which is coupled to a secondary heat conductor dissipating heat to ambient.

FIG. 10 is a flowchart illustrating operations according to some embodiments of the invention.

### DETAILED DESCRIPTION OF EMBODIMENTS OF THE INVENTION

The present invention now will be described more fully with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or body is referred to as being “on” another element, it can be directly on the other element or intervening elements may also be present. It will be understood that if part of an element, such as a surface, is referred to as “inner”, it is farther from the outside of the system than other parts of the element. Furthermore, relative terms such as “beneath” or “overlies” may be used herein to describe a relationship of one layer or region to another layer or region relative to a substrate or base layer as illustrated in the figures. It will be understood that these terms are intended to encompass different orientations of the system in addition to the orientation depicted in the figures. Finally, the term “directly” means that there are no intervening elements. As used herein, the term “and/or” includes any and all combinations of one or more of the associated listed items.

It will be understood that, although the terms first, primary, second, secondary, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings or the present invention.

Embodiments of the invention are described herein with reference to cross-sectional, perspective, and/or plan view illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a region illustrated or described as a rectangle will, typically, have rounded or curved features due to normal manufacturing tolerances. Thus, the regions illustrated in the figures are schematic in nature and their shapes are not intended to illustrate the precise shape of a region of a device and not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Some embodiments of the present invention relate to upper-level packaging, or fixturing, of electrical components. As used herein, the term electrical component may include an integrated circuit (IC) device, an application specific integrated circuit (ASIC), a power field effect transmitter (FET), a Light Emitting Diode (LED), laser diode and/or other semiconductor component or device which includes one or more semiconductor layers, which may include silicon, silicon carbide, gallium nitride and/or other semiconductor materials. For example, the semiconductor light emitting device may be gallium nitride-based LED sold as a surface mount high-power component such as those manufactured and sold by Cree, Inc. of Durham, N.C. Other examples of semiconductor devices could be high power LED components from Lumileds, Osram, Nichia, etc. which are generally considered lighting class products.

Solder is commonly used to make electrical and thermal connections for high-power LED components. Some embodiments of the present invention use solder to make the thermal connection between the LED component and the primary heat conductor as well as make the electrical connections to wire or PCB/PWB. Solder is a general category consisting of various alloys that can be reflowed to form metallurgical bonds between various metals. Common solders that would be used for this type application would be high temperature solders such as gold-tin eutectic solders (80/20 Au/Sn), lead-free solders such as tin-silver-copper alloys (97/2.5/0.5 Sn/Ag/Cu), or tin-lead alloys (63/37 Sn/Pb). For the purposes of these embodiments, the materials or structures which are referred to as being solder attached, are assumed to be able to be wetted by solder, or to have a plating such that the plating is able to be wetted by solder, such that a metallurgical bond is formed assuring good electrical or thermal conductive properties.

Some embodiments of the present invention can use means other than solder to make electrical and thermal connections. Methods such as electrically conductive adhesive (Ag-filled epoxy is common), conductive inks, mechanical contact, etc. are used for electrical connections. Thermal connections are commonly made with thermal-compound (commonly known as thermal grease), mechanical contact, thermal pads, etc. to achieve acceptable thermal conductivity. In general solder provides the most economical and best method for electrical and thermal connections, so following discussions will reference solder, however it is to be understood that this is not limiting other methods to make electrical or thermal connections.

By the same token, some embodiments of the present invention reference metallurgical bonding/joining which include methods of brazing or welding. Brazing is commonly defined as using a filler metal or alloy and higher temperatures than soldering to form a metallurgical bond. Post processes such as annealing are commonly used after brazing to increase strength of the bond. Welding is also a common method where metal is coalesced to form a bond. Many different methods and material combinations can be used to form welded joints and these are considered commonly known to people skilled in the art.

Heat energy is generally referred to as being dissipated to ambient. For the purposes of this invention, ambient is a general term that represents a significantly larger thermal mass at a lower energy state. This is generally taken as the surrounding atmosphere, or large pool of water, or convective air stream, much larger metal structure, or many other cases which would be understood by those skilled in the art of heat dissipation. For purposes of this discussion, ambient is understood to be a relatively infinite heat sink for heat energy.

In some embodiments of the invention, the term rod or bar imply a circular or square cross-sectional shape. These shapes are generally commonly available and are used for ease of explanation. The terms rod and bar are not meant to be exclusive but are meant to refer to any physical volume/shape that extends significantly more in one dimension than the other two dimensions.

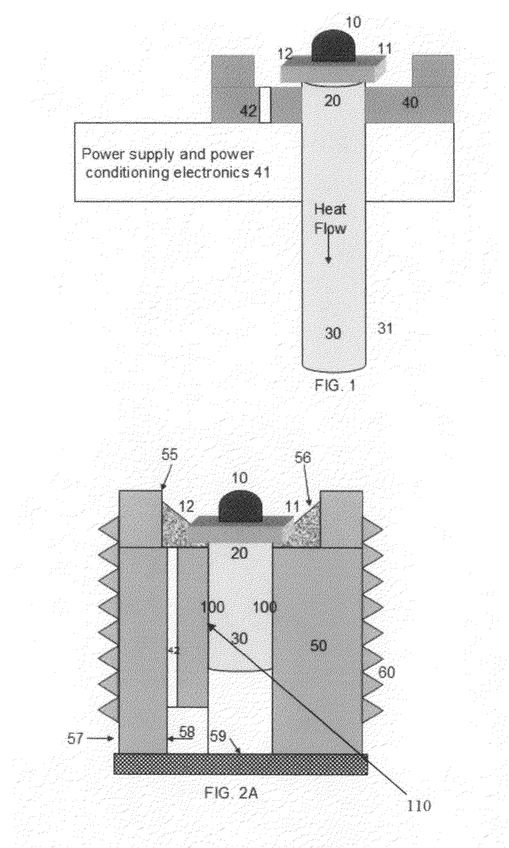

A heat dissipation system with low thermal resistance for the packaging of high power electrical components, and the methods for assembling a low thermal resistance system, is proposed. Unique in this method is the emphasis on moving heat with a primary thermal conductor away from the source and creating large area interface zones to improve heat transfer. In FIG. 1, an electrical component 10, in some embodiments a high-powered LED component, is shown with electrical connections 11 and 12, to supply power and possibly signals to the electrical component 10. Typically a high power electrical component has a thermal pad, commonly a bottom surface, for connection to dissipate heat away from the component. In FIG. 1, 20 represents the thermal connection, typically soldered, between the thermal pad of 10 and the primary heat conductor 30. FIG. 1 shows that the primary heat conductor 30 extends a significant distance away from 20 to reach ambient conditions through the interface at 31. Some embodiments of 30 would include an oxygen-free Copper rod to provide a good soldering surface as well as excellent thermal conduction. With excellent thermal conduction properties, heat can be transported from 20 through surrounding structures. In FIG. 1, surrounding structure 40 is part of a structural system which may include passthroughs 42 for power/signal wiring. 40 may also provide structural support for PWB/PCB or wiring connections to 11 and 12. As shown in FIG. 1, surrounding structure 41 may also be passed through to get to ambient conditions. 42 may be additional structural elements or may include power supply or power-conditioning electronic elements. The interface at 31, in some embodiments may include features to increase the surface area for greater dissipation to ambient per unit length. By allowing a direct path for heat from 20 to ambient via an excellent thermal conductor, a large aspect ratio can be utilized as there are no more transitions/connections to be made before reaching ambient conditions.

The utilization of a highly thermal-conductive primary heat conductor 30, allows for packaging options not previously available for high power electrical components. In some embodiments, 30 is a ¼ inch diameter Oxygen-free Copper rod that has a length of 6 inches with the last 3 inches exposed to ambient. This gives an aspect ratio of length to attach-width of 24. Embodiments of this invention have an aspect ratio of length to width greater than 1. Typical primary heat conductors such as might be found in a MCPWB/MCPCB for high-power electrical components might have a length to attach-width ratio of 0.3 or less. When multiple electrical components are desired on a MCPWB/MCPCB/PWB/PCB for example the thermal management problem becomes a limiting packaging design constraint.

In some embodiments of the invention, the primary heat conductor 30 could have a shape designed to match the electrical component 10 thermal pad for optimal fit. In other embodiments, the primary heat conductor 30 could have a machined or formed end such that the thermal connection 20 is sized to match the electrical component 10. In other embodiments the primary heat conductor 30 will have a larger diameter/area than the thermal pad of the electrical component 10 in order to accommodate greater heat conduction through spreading as well as vertical transfer along the length of the primary heat conductor 30.

In some embodiments of the invention as shown in FIG. 1, the primary thermal conductor 30 is a structural support for 40 and 41. In other embodiments of the invention, the primary thermal conductor 30 is not a structural component for the assembly and this is provided by 40 and/or 41.

In some embodiments of the invention, the primary heat conductor 30 is also functioning as one of the power/signal leads for 11 or 12 that go to the electrical component 10. As many of the ambient conditions typically used are not conductive, such as air, this would allow packaging freedom to move the interconnection point to the power supply to a more convenient position for that lead. Also as a result of joining one of the leads 11 or 12 to 30, a larger diameter rod/bar could be used, without special features, as the primary heat conductor 30 and could then span the distance of the thermal pad of 10 as well as one of the leads 11/12 and thus simplify top side interconnections.

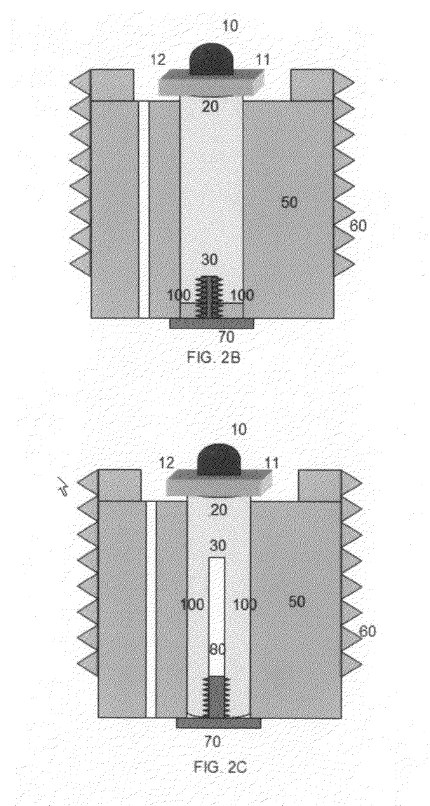

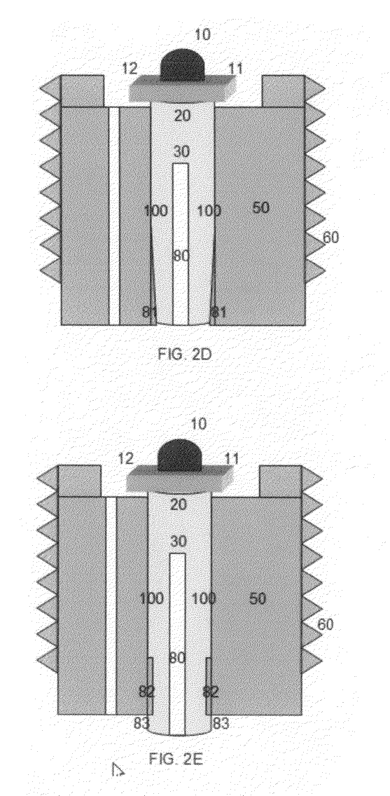

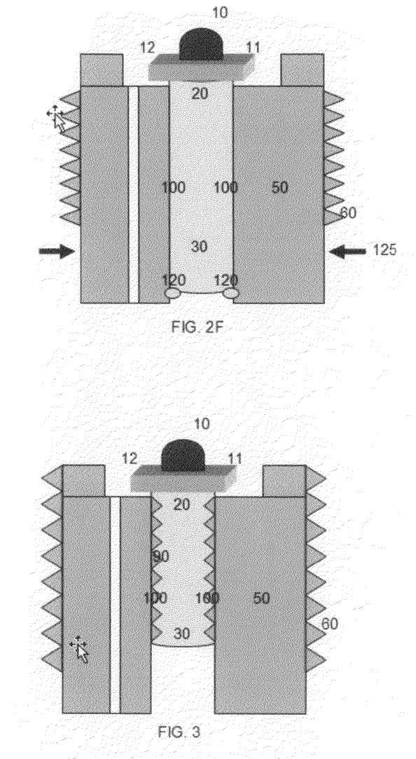

The heat dissipation system in FIG. 2A includes a secondary heat conductor 50. Heat energy flows from the electrical component 10, through the thermal connection 20 to the primary heat conductor 30, and through the interface 100 which is between the primary and secondary heat conductors to 50. From the secondary heat conductor 50, the heat energy is dissipated to ambient at the interface 60 which may or may not have special surface area increasing features to promote faster dissipation. There are several advantages to this embodiment using a secondary heat conductor 50.

In some embodiments of the invention in FIG. 2A, material advantages can be gained. As Oxygen-free Copper is an optimal choice for 30, Aluminum in an optimal choice for 50. By making the secondary heat conductor 50 out of Aluminum, cost is reduced. The primary heat conductor 30 is providing optimal heat transfer away from the electrical component 10, and providing a large surface area 100 by means of the high aspect ratio of 30. As compared to FIG. 1, the aspect ratio for 30 can be much less, in some embodiments between 1 and 4. This reduced aspect ratio of 30 is bettered, in terms of heat transfer, by the increased surface area of 50 in closer proximity to the heat generation source of 10.

In some embodiments of the invention in FIG. 2A, advantages are gained as the secondary heat conductor 50 provides the structural support for the electrical component 10. In some embodiments of the invention in FIG. 2A, 50 provides the structural support for the power supply and power conditioning components as shown in cavities formed by features such as 58. The secondary heat conductor 50 can also form the bulk of a standalone structure such as a handheld lighting device. In other embodiments, the structure provided by the secondary heat conductor 50 is mated to other structures by designed features 57 such as a machined diameter to provide coupling to other structures 59 which provide aesthetic qualities or other functional structural features such as light-weight handles or buoyant handles or different size structural components and cavities.

In some embodiments of the invention in FIG. 2A, structural features such as 55 are employed to provide physical, mechanical, and electrical-shorting protection for electrical component 10 and to provide a cavity for sealants to protect the component 10. In some embodiments of the invention a waterproof sealant 56 is applied in the cavity to provide underwater use capability as well as light reflection/direction properties.

In some embodiments of the invention, the secondary heat conductor 50 is surface treated, such as with an anodizing process, to provide saltwater corrosion protection at the interface 60.

In further discussions regarding the heat dissipation systems of this invention, the structural discussions in the previous 5 paragraphs referencing structural features in FIG. 2A will apply as well to all included figures showing a secondary heat conductor 50 as well as they would apply to structures 40 and 41 in FIG. 1.

In order to achieve best thermal transfer between the interface 100 in FIG. 2A, a close fit between the primary heat conductor 30 and the secondary heat conductor 50 is needed. In some embodiment of the invention, this fit can be achieved with a precise machining of the piece-parts.

In some embodiments of the invention, an improved fit between the primary and secondary heat conductors, 30 and 50, can be obtained by using a method to take advantage of the CTE of the materials. If the secondary heat conductor 50 is thermally expanded by heating, a slight but measurable gain in inner diameter is achieved. Correspondingly, the primary heat conductor 30 can be cooled and a slight reduction in outer diameter will be realized. If the two pieces are made to be assembled while 50 is thermally expanded and 30 is thermally contracted, then once the temperatures have reached equilibrium at interface 100, the fit will be improved (i.e. more closely coupled) and heat transfer will be more efficient.

In some embodiments of the invention as shown in FIG. 2A, the thermal interface 100 can be enhanced with the use of a thermal compound 110 for conducting heat between the primary and secondary heat conductors 30 and 50 respectively. Thermal compound 110 can range from thermal grease specially formulated for high heat conductive properties to any fill material that displaces air gaps.

In some embodiments of the invention as shown in FIG. 2B, a mechanical fastener 70 can be used to ensure a high conductive interface 100 is maintained between the primary heat conductor 30 and the secondary heat conductor 50. Also working to the advantage of heat conduction is that in some embodiments a threaded-fastener 70 provides a large contact surface area with the primary heat conductor 30 and acts as a thermal conductor to the secondary heat conductor 50.

In some embodiments of the invention as shown in FIG. 2C, a mechanical fastener 70 can be used to expand outward the primary heat conductor 30, which has a slotted feature 80 allowing expansion, to enhance the thermal interface 100 to the secondary heat conductor 50. The wedging action of the fastener can be achieved with or without a threaded fastener. A tapered shape to the fastener 70 may be employed to ease assembly.

In some embodiments of the invention as shown in FIG. 2D, designed features such as 81 in the secondary heat conductor 50 which can be a reduction in the inner diameter can utilize elastic spring force of materials in the primary heat conductor 30 allowed by a slotted feature 80, to enhance and ensure the thermal interface 100 to the secondary heat conductor 50.

In some embodiments of the invention as shown in FIG. 2E, locking features 83 and 82 designed into the primary and secondary heat conductors 30 and 50 respectively can ensure good thermal contact is always maintained. In some embodiments, feature 83 alone will work without feature 82 as feature 80 provides spring action allowing 83 to lock into position on 50.

In some embodiments of the invention as shown in FIG. 2F, metallurgical bonding 120 by soldering, brazing, welding, chemical bonding, etc. is used to ensure direct thermal connection between the primary and secondary heat conductors 30 and 50 respectively. In other embodiments of the invention, deformation processes such as crimping depicted by 125, can ensure good thermal connection at interface 100. During metal deformation processing such as crimping, surface roughness or surface features of surfaces coming into contact can be tuned to provide excellent thermal contact results.

In some embodiments of the invention as shown in FIG. 3, the primary heat conductor 30 is threaded to mate with the secondary heat conductor 50 to form a threaded interface 90 which greatly increases the surface area of 100 as compared to non-threaded versions. Torque applied to threads assures that contact is maintained.

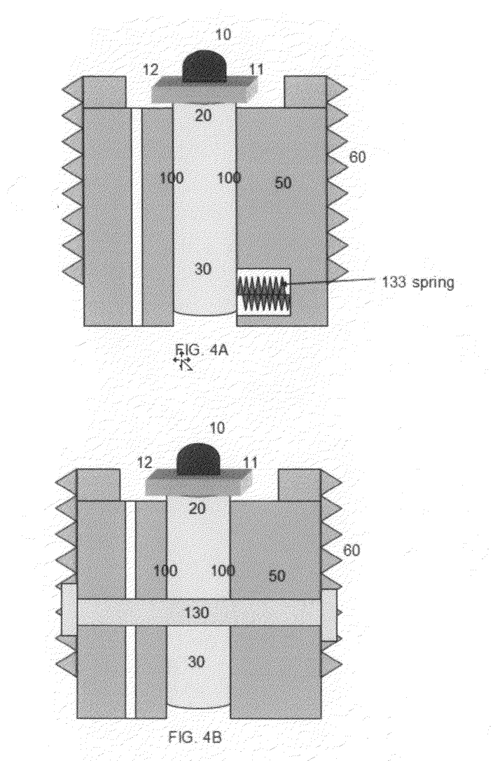

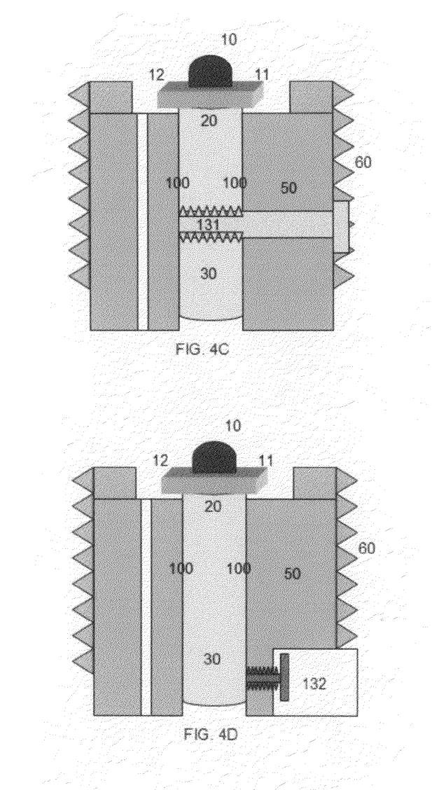

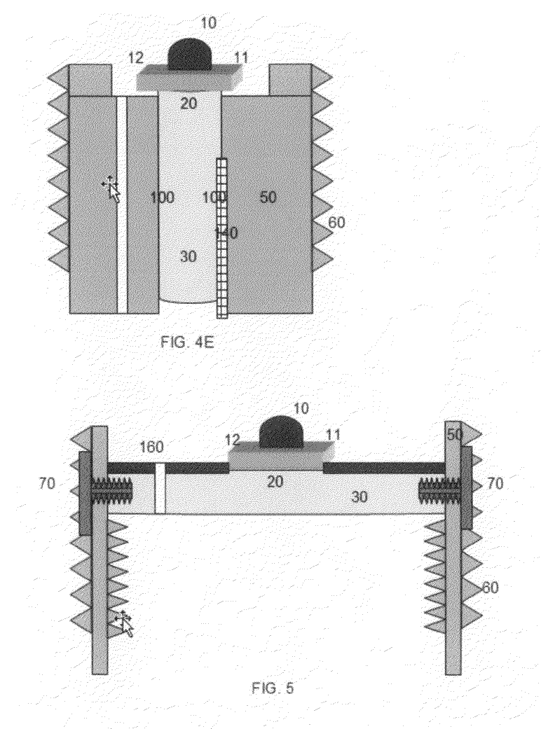

In some embodiments of the invention as shown in FIG. 4A, a force can be exerted by a spring 133 to keep constant contact between heat conductors 30 and 50 maintaining a consistent interface 100 for thermal energy transport.

In some embodiments of the invention as shown in FIG. 4B, a fastener 130 can pass through the primary and secondary heat conductors, 30 and 50, to enhance the thermal interface 100 as well as provide a further heat conduction path. In some embodiments of the invention this fastener 130 may be a bolt, or a rivet, or threaded along the length to enhance thermal flow to ambient.

In other embodiments of the invention, as shown in FIG. 4C, a fastener 131 is threaded and does not pass through both the primary and secondary heat conductors, 30 and 50. As depicted, the primary heat conductor is tapped to receive the threads of the fastener assuring that a firm contact can be maintained at the interface 100 for heat transfer to the secondary heat conductor. The force applied by the fastener is a pulling force on the primary heat conductor 30 locking it to the secondary heat conductor 50. Thermal transport will also occur along the threaded fastener 131. In other embodiments, as shown in FIG. 4D, a threaded fastener 132 can be used to exert a pushing force, or pinning of the primary heat conductor 30 against the secondary heat conductor 50.

In some embodiments of the invention as shown in FIG. 4E, and additional heat conducting component 140 is inserted between the primary and secondary heat conductors, 30 and 50, to facilitate transfer of energy. In some embodiments this component 140 is press-fit between 30 and 50 to assure good contact. In other embodiments, this is inserted using the thermal expansion of 50 and thermal contraction of 30 technique as depicted in FIG. 10 to allow high contact fit during equilibrium states. In other embodiments of FIG. 4E, the component 140 is not a high thermal conductivity material but a material with high CTE causing it to expand faster than surrounding material assuring that a force is applied to make the thermal interface 100 have a low thermal resistance. In other embodiments, there are multiple component 140s per primary heat conductor 30.

In some embodiments of the invention as depicted in FIG. 1-4E, there can be multiple electronic components 10 per Primary heat conductor 30. As well, there can be multiple electronic components 10 on multiple primary heat conductors 30 per heat dissipation system. As more wattage is applied to drive more electrical components, the more critical the thermal resistance of the system for optimal component performance.

Depicted in FIG. 5 is an embodiment showing a cross-section of a system that is easily expandable for multiple electrical components 10 on a single primary heat conductor 30. The secondary heat conductor 50 is shown with the interface to ambient 60 with increased surface area fins on multiple surfaces. In some embodiments, 50 is envisioned to be a U-Channel or I-Beam shape which would allow multiple primary heat conductors 30 to be attached, with single or multiple electrical devices 10 per 30. In some embodiments, a PCB/PWB 160 provides the electrical connections to the electronic device and in some embodiments provides a surface for protecting and in some embodiments sealing structural and electrical components for waterproof operation. In some embodiments, the secondary heat conductor 50 provides baffling for convective cooling assist.

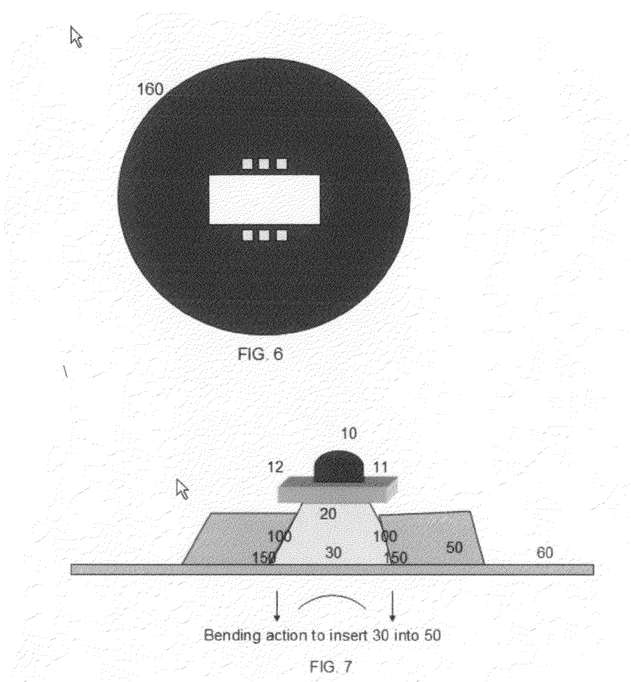

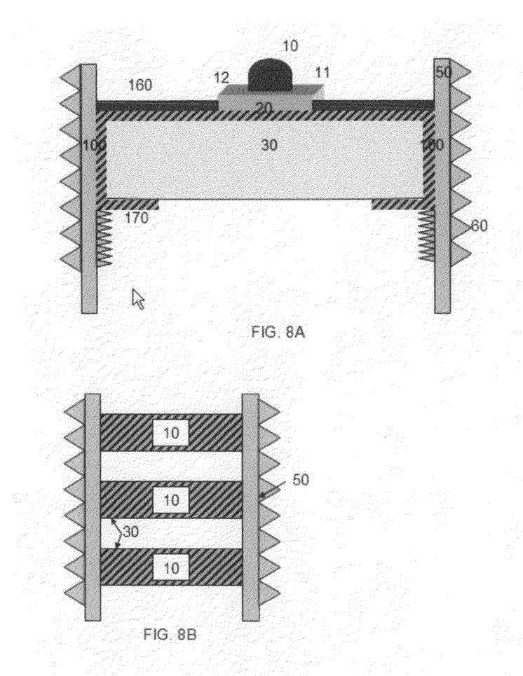

FIG. 6 is top view of and embodiment of a PWB/PCB 160 which has a rectangular cutout so that it can be assembled and soldered to an electrical component post soldering the electrical component to the primary heat conductor. This rectangular cutout allows the PWB/PCB to be place over certain rectangular shaped components, such as the MC series of LEDs manufactured by Cree Inc., and then rotated into position so that the connection pads of the PWB/PCB align with the pads of the electrical component. This method of assembly allows the critical assembly steps for heat transfer from primary heat conductors to ambient, to be unencumbered by the electrical connectivity of the electrical component.

In some embodiments of the invention as shown in FIG. 7, the thermal interface 100 between the primary heat conductor 30 and the secondary heat conductor 50 is maintained by spring force from the secondary heat conductor 50. By designing mating angles 150 of the heat conductors 30 and 50, and designing the secondary heat conductor 50 such that it may be flexed with a bending action to open the cavity enough to slide the primary heat conductor 30 into the opening so that when the bending moment is removed from 50, the increased opening will close and provide a constant clamping spring force onto 30 maintaining a good thermal interface 100. The secondary heat conductor 50 in this embodiment may be made up of several pieces as it can be envisioned that one of more of the clamping pieces could be locked or installed during the flexing moment to aid assembly and simplify the insertion of 30. In some embodiments of this approach, it can be envisioned that post insertion of the primary heat conductor 30, that the secondary heat conductor 50 is flexed or has a moment applied to create a clamping force on the thermal interface 100 assuring good thermal transfer.

In some embodiments of the heat dissipation system shown in FIG. 7, the secondary heat conductor 50 contains a plurality of primary heat conductors 30. In other embodiments, a single primary heat conductor 30 contains a plurality of electrical components 10. In other embodiments, a single primary heat conductor 30 contains a plurality of electrical components 10 and a plurality of secondary heat conductors 50.

In some embodiments of the heat dissipation system shown in FIG. 8A, the primary heat conductor 30 is wrapped around the ends of an expansion-body 180. The expansion-body 180 is chosen so that the CTE is equal or greater than the CTE of the primary heat conductor 30. It is also chosen so that the CTE properties will expand the expansion-body such that good thermal interface 100 contact will always be maintained between the primary heat conductor 30 and the secondary heat conductor 50. In some embodiments, the wrapping of the primary heat conductor 30 continues to the bottom side of the expansion-body 180 as shown by 170. In some embodiments, the wrapping of the primary heat conductor 30 and the expansion-body assembly are pressed/formed to exact fit dimensions to the secondary heat conductor 50. In some embodiments, the method of assembly utilizes the CTE of materials as shown in FIG. 10. PWB/PCB 160 is shown in FIG. 8A and may or may not be used to make the electrical connections. In FIG. 8B, in a top view without showing the PWB/PCB or wired connections, a plurality of electrical devices and plurality of primary heat conductors 30 can be seen. In some embodiments, individual expansion-bodies 180 go with individual primary heat conductors 30. In other embodiments, many primary expansion bodies wrap around a single expansion-body. In yet other embodiments, a plurality of electrical components 10 can be in several combinations of arrangement.

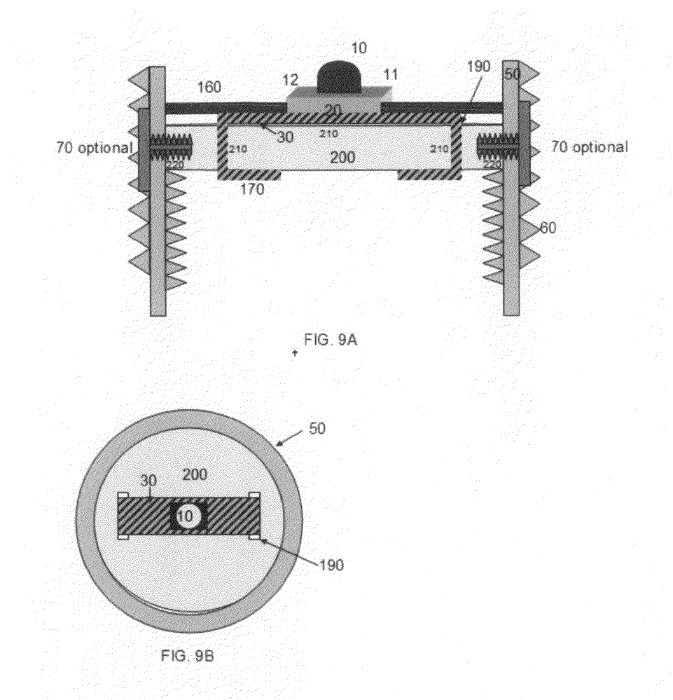

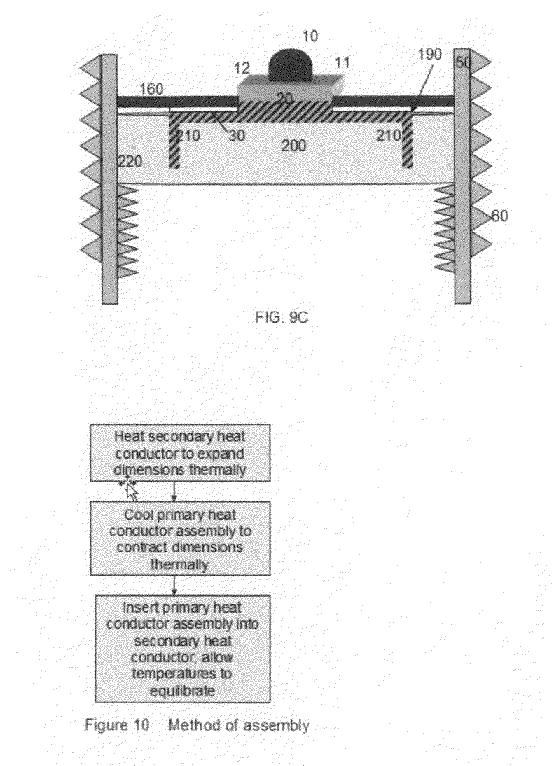

In some embodiments of the heat dissipation system shown in FIG. 9A, the primary heat conductor 30 is made from a high thermal conductivity material with relatively low CTE properties like Copper. This is then inserted into a primary-heat-spreading-body 200 which has the function of taking energy from the primary heat conductor 30 through interfaces 210 and spreading the heat energy to the secondary heat conductor 50 through interface 220. In some embodiments, the primary-heat-spreading-body 200 has an equivalent or higher CTE property than the primary heat conductor 30 which will ensure a good contact at interface 210. In some embodiments, the method of assembly depicted in FIG. 10 is used to insert the primary-heat-spreading-body 200 assembly into the secondary heat conductor 50. In other embodiments, fasteners 70, or methods such as metallurgical bonding, thermal compounds, metal deformation such as crimping, etc. can be used to assure good contact at interface 220. Callout 170 points to a wrap-around design where the primary heat conductor 30 is inserted through the primary-heat-spreading-body and then formed to assure a tight and secure St. Callout 190 in FIGS. 9A and 9C point to a radius on entrance to alleviate high stress points. FIG. 9C shows a design where the primary heat conductor 30 is inserted into the primary-heat-spreading-body 200 versus through 200. The primary heat conductor 30 could be fastened, or adhered with a thermal compound, or crimped, or various methods to assure a good contact at interface 210. FIG. 9B shows a top-view of an electrical component 10, such as a high power LED component, on a Copper strip that is inserted into an Aluminum primary-heat-spreading-body. The Aluminum heat spreader is shown inserted into Aluminum tubing which has high surface area due to its large diameter for ambient transfer. The PWB/PCB or wiring for interconnection to 10 is not shown in FIG. 9B.

What is claimed is:

1. A heat dissipation system comprising:
an electrical component;
electrical connections for power/signal on the electrical component;
a thermal connection for heat dissipation on the electrical component;
an electrical connection component(s);
and a primary heat conductor, which is separate from the electrical interconnection components, which is coupled to the thermal connection pad for the electrical component and transfers the heat away from the electrical component and dissipates the heat energy to ambient.

2. The heat dissipation system of claim 1, wherein the primary heat conductor also comprises one of the electrical interconnections.

3. The heat dissipation system of claim 1, wherein the primary heat conductor passes through a structural support system to reach ambient conditions.

4. The heat dissipation system of claim 1, further comprising a secondary heat conductor, wherein the secondary heat conductor is essentially surrounding and thermally coupled to the primary heat conductor, and the secondary heat conductor provides the heat transfer path to ambient.

5. The heat dissipation system of claim 4, wherein the secondary heat conductor provides structural support for the electrical component.

6. The heat dissipation system of claim 4, wherein the secondary heat conductor provides a housing for protecting and waterproofing the electrical component and electrical interconnections.

7. The heat dissipation system of claim 4, wherein the secondary heat conductor is thermally coupled to the primary heat conductor by a precise machining fit between the heat conductors.

8. The method of claim 7, wherein the secondary heat conductor is thermally expanded relative to the primary heat conductor prior to insertion.

9. The heat dissipation system of claim 4, wherein the thermal interface between the primary and secondary heat conductor is enhanced with thermal-interface-compound.

10. The heat dissipation system of claim 4, wherein the thermal interface between the primary and secondary heat conductor is maintained with the aid of mechanical fastening.

11. The heat dissipation system of claim 4, wherein the thermal interface between the primary and secondary heat conductor is maintained by spring force.

12. The heat dissipation system of claim 4, wherein the thermal interface between the primary and secondary heat conductor is formed by metallurgical joining of the two conductors.

13. The heat dissipation system of claim 4, wherein the thermal interface between the primary and secondary heat conductor is enhanced by crimping the two conductors together.

14. The heat dissipation system of claim 4, further comprising an additional heat conducting component for the purpose of enhancing heat transfer between the primary heat conductor and the secondary heat conductor.

15. The heat dissipation system of claim 4, wherein the thermal interface between the primary and secondary heat conductor is enhanced by inserting a body between the primary and secondary heat conductors.

16. The heat dissipation system of claim 1, further comprising multiple electrical components on the primary heat conductor.

17. The heat dissipation system of claim 4, further comprising multiple electrical components on multiple primary heat conductors.

18. A heat dissipation system comprising:
an electrical component;
a thermal connection for heat dissipation from the electrical component;
a primary heat conductor,
and an electrical-connection-component which has a shaped cutout such that the electrical-connection-component can be inserted over, rotated, and then soldered after attachment of the primary heat conductor.

19. The method of claim 4, whereby the secondary heat conductor is flexed to expand a cavity allowing the insertion of the primary heat conductor.

20. The method of claim 19, whereby the secondary heat conductor is flexed post insertion providing a bending moment to maintain tight contact between the primary and secondary conductors.

21. The heat dissipation system of claim 19, with a plurality of electrical components.

22. A heat dissipation system comprising:
an electrical component;
a thermal connection for heat dissipation from the electrical component to a primary heat conductor,
a primary heat conductor,
an expansion body,
a secondary heat conductor,
and an assembly of the primary heat conductor wrapped around the outside of the expansion body, which is then inserted into the secondary heat conductor for transfer of heat to the secondary heat conductor.

23. The method of claim 22, whereby the Coefficient of Thermal Expansion (CTE) of the expansion body is greater than the primary heat conductor assuring a good interface is maintained.

24. The method of claim 22, whereby the assembly of the primary heat conductor and the expansion body is cold relative to the thermally-expanded secondary heat conductor during assembly.

25. The heat dissipation system of claim 22, wherein there is a plurality of electrical components.

26. A heat dissipation system comprising:
an electrical component;
a thermal connection for heat dissipation from the electrical component to a primary heat conductor;
a primary heat conductor,
a primary-heat-spreading body,
a secondary heat conductor,
and an assembly of the primary heat conductor for thermally coupling to the primary-expansion body, which is then inserted into the secondary heat conductor for transfer of heat to ambient.

27. The method of claim 26, whereby the Coefficient of Thermal Expansion (CTE) of the primary-heat-spreading body is greater than the primary heat conductor assuring a good interface is maintained.

28. The method of claim 26, whereby the assembly of the primary heat conductor and the primary-heat-spreading body is cold relative to the thermally-expanded secondary heat conductor during assembly.

29. The heat dissipation system of claim 26, wherein the primary heat conductor is thermally coupled to the primary-heat-spreading body.

30. The heat dissipation system of claim 26, wherein the secondary heat conductor is mechanically fastened to the primary-heat-spreading body.

31. The heat dissipation system of claim 26, wherein there is a plurality of electrical components.
